(19) United States
(12) Patent Application Publication
(10) Pub. No.: US 2024/0166066 A1
(43) Pub. Date: May 23, 2024

(54) MODULAR, EXPANDABLE, PREFABRICATED CHASSIS FOR ELECTRICAL VEHICLE CHARGING STATIONS

(71) Applicant: DC-AMERICA, LLC, MILTON, WV (US)

(72) Inventors: Nathan Bowen, Barboursville, WV (US); Chuck King, Culloden, WV (US)

(21) Appl. No.: 18/366,772

(22) Filed: Aug. 8, 2023

Related U.S. Application Data
(60) Provisional application No. 63/384,236, filed on Nov. 18, 2022.

(51) Int. Cl. B60L 53/31; H05K 5/02

(52) U.S. Cl. CPC B60L 53/31; H05K 5/0217; H05K 5/0247

(57) ABSTRACT

A modular, expandable, prefabricated chassis for EV charging stations useful in supporting a plurality of EVSE charging posts, including a support housing through which power and communications cabling is channeled, and a connection cabinet affixed to the support housing for receiving power from a utility, and disbursing it through the cabling. Also, a modular, portable EV charging station, including a chassis and a plurality of EVSE charging posts affixed to the support housing, wherein power cables, the electrical wire and the communications cabling from the support housing are electrically or communicatively coupled with the EVSE charging post. Also, a method of installing an EV charging station at a site, the method including the transport of a fully assembled EV charging station to a site, positioning the EV charging station on a solid pad provided at the site, and connecting utility lines to the connection cabinet of the EV charging station.

This application claims priority to U.S. Provisional Patent Application Ser. No. 63/384,236, titled MODULAR ELECTRIC VEHICLE CHARGING SYSTEMS WITH INTEGRATED EXPANSION CAPABILITIES, filed with the US Patent and Trademark Office on Nov. 18, 2022, the entire disclosure of which is hereby incorporated by this reference.

### FIELD OF THE INVENTION

The disclosed technology provides a modular, expandable, prefabricated electrical vehicle charging station chassis capable of supporting and supplying energy to a variety of electrical vehicle supply equipment (EVSE) charging posts. The disclosed technology also provides a modular, expandable, prefabricated electrical vehicle charging station. Further, the disclosed technology provides a method of installing an electrical vehicle charging station.

### BACKGROUND

Supply equipment for electric vehicles (EVs) are classified by the rate at which they charge vehicle batteries, and EVSE stations presently in operation typically offer Level 2 Charging and/or DC Fast Charging equipment. Manufacturers of EVSE stations include ChargePoint, ABB, Autel, Heliox, BTC, Delta, KemPower, and many others.

These EVSE stations are installed at commercial sites, wherein each EVSE charging post is independently supplied electrical energy by means of power cables originating from a utility power source and distributed through a main distribution panel, and receives and transmits information by means of communications cables to a remote cable, cellular or satellite modem (and computer processing equipment), all of the cables being installed underground. This design results in a highly technical in situ installation, in many instances requiring a labor force trained through the Electric Vehicle Infrastructure Training Program (EVITP). While this trained labor force is growing, the limited number of EVITP trained individuals correspondingly limits the number of stations that can be installed in any given year, and substantially increases the expense of installation. Further, the underground cable design is difficult to maintain and upgrade.

EVSE equipment, especially DC Fast Charging equipment, also adds a considerable amount of peak demand to a commercial electrical service, and many utility companies charge a base rate plus a demand charge based on peak demand.

Therefore, there is a need for modular, expandible, prefabricated chassis for electrical vehicle charging stations, capable of simple installation, expansion and upgrade, which can minimize electrical demand during peak hours and the associated demand charges. Further, there is a need for modular, prefabricated charging stations, and methods to simplify the installation of EV charging stations.

### GENERAL DESCRIPTION

The disclosed technology provides a modular, prefabricated chassis for EV charging stations, capable of customization for different site configurations and customer requirements, simple installation and rapid deployment. The disclosed technology further provides a modular, prefabricated EV charging station. Further, the disclosed technology provides a method of installing an EV charging station.

Using the disclosed technology, EV station assembly can be accomplished offsite by an EVITP trained labor force, and quickly installed on site by less skilled electricians, wherein only a single power, 3 conductor cable (in many instances, buried underground) coupled with a transformer is required.

Further, the disclosed technology provides simple and efficient means for expanding the chassis to add additional EVSE charging posts at a site, and for scaling up by, for example, replacing a Level 2 Charging system with a DC Fast Charging system, or future developed EVSE systems.

The system of the disclosed technology may also minimize the impact on peak demand for electrical services, and the associated charges, by utilizing one or more energy storage systems (i.e., batteries) that are charged at non-peak times (and rates) and/or by photovoltaic elements. For example, solar photovoltaic roofing and other photovoltaic components may be provided to supply energy to the energy storage system and the electrical components of the system. When positioned above the station, these components may also limit exposure of the EVSE charging posts and the EV charging station to weather conditions such as rain and snow.

Additionally, cloud-based open charge point protocol (OCPP) may be used with the EVSE of the disclosed technology, providing smart charging, dynamic load management and energy use optimization, and up to an 80% decrease on premise maintenance. Other strategies may also be implemented to utilize OCPP to charge the EVSE when rates are lowest, particularly useful in locales that charge more for peak time use.

Additional, optional components provided in the prefabricated EVSE charging stations of the disclosed technology may include an integrated television screen, security cameras, and LED lighting affixed about the station and the supporting structure. Further, dispenser protection bollards may be provided on the station, as well as air compressors and vacuum cleaners.

All of these and other features of the disclosed technology provide significant cost savings, increase rate of deployment, and minimize site disturbance and station footprint.

Generally, the disclosed technology provides a modular, expandable, prefabricated chassis for EV charging stations useful in supporting a plurality of EVSE charging posts. As hereinafter described through embodiments, the chassis includes a support housing presenting as an enclosed, modular, raised platform, with a plurality of EVSE charging post positions defined thereon, and a port at each said EVSE charging post position.

A connection cabinet is affixed to the support housing, having a master circuit breaker and electrical circuitry capable of receiving electricity from a power source, and distributing the electricity to a plurality of power supply cables and a plurality of electrical wires. The connection cabinet further includes communication cabling, and various communication equipment. In this configuration, the power supply cables, electrical wires and communication cabling are routed from the connection cabinet through the support housing to the EVSE charging post positions.

Provided within the interior of the support structure are a plurality of cable supports, the cable supports facilitating and managing the routing of power supply cables, electrical wires and/or communications cabling through the support housing and to the port of the support housing at the EVSE charging positions.

Further, the disclosed technology provides a modular, portable EV charging station, including a chassis as hereinabove described, and a plurality of EVSE charging posts affixed to the support housing at one or more of the EVSE charging post positions, wherein the power cables, the electrical wire and the communications cabling are electrically or communicatively coupled with the EVSE charging post.

Finally, the disclosed technology offers a method of installing an EV charging station at a site, the method including the transport of an EV charging station as hereinabove described, to a site, positioning the EV charging station on a solid pad provided at the site, and connecting utility lines to the connection cabinet of the EV charging station.

### DESCRIPTION OF THE DRAWINGS

FIG. 1 is an isometric view of an embodiment of a modular, prefabricated charging station of the disclosed technology, having an embodiment of a chassis of the disclosed technology, and installed at a site using an embodiment of the method of the disclosed technology.

FIGS. 2A and 2B are respective end views of the support housing of the embodiment of FIG. 1, wherein FIG. 2A shows the cabling at the end of the rectangular pad (left side of FIG. 1), and FIG. 2B shows the cabling at the end of the elongated tube (right side of FIG. 1), with respective end caps removed.

FIG. 3 shows an end view of an internal lifting lug positioned on a wall of an exterior channel traversing the perimeter of the interior of an embodiment of the support housing of the disclosed technology.

FIG. 4A shows a perspective view of an end cap useful in the chassis of the disclosed technology to facility expansion of the station in situ; FIG. 4B and FIG. 4C show a perspective view of different extenders useful in expansion of the station.

FIG. 5 shows a perspective view of the base of an EVSE charging post as affixed to the chassis of the disclosed technology.

FIG. 6 shows a front view of a strong eye bolt affixed to a post, useful in transport of the disclosed technology.

FIG. 7 is a perspective view of another embodiment of a modular, prefabricated charging station of the disclosed technology, having an embodiment of a chassis of the disclosed technology, and installed at a site using an embodiment of the method of the disclosed technology.

FIG. 8 is a perspective view of another embodiment of a modular, prefabricated charging station of the disclosed technology, having an embodiment of a chassis of the disclosed technology, and installed at a site using an embodiment of the method of the disclosed technology.

FIG. 9 is an electrical schematic of an embodiment of the connection cabinet of the disclosed technology.

FIG. 10A is a perspective view of another embodiment of a modular, prefabricated charging station of the disclosed technology with an enclosing facility, having an embodiment of a chassis of the disclosed technology, and installed at a site using an embodiment of the method of the disclosed technology.

FIG. 10B is a perspective view of the station of FIG. 10A, with the enclosing facility removed.

FIG. 11A is a perspective view of another embodiment of a modular, prefabricated charging station of the disclosed technology, having an embodiment of a chassis of the disclosed technology, and installed at a site using an embodiment of the method of the disclosed technology.

FIG. 11B is a perspective view of a leveler of the disclosed technology, positioned below a portion of a module of the disclosed technology.

FIG. 12 is a side view of a portion of another embodiment of a modular, prefabricated charging station of the disclosed technology, having an embodiment of a chassis of the disclosed technology, and installed at a site using an embodiment of the method of the disclosed technology.

FIG. 13 is a perspective view of another embodiment of a modular, prefabricated charging station of the disclosed technology, having an embodiment of a chassis of the disclosed technology.

FIG. 14 is a perspective view of a module of the chassis supporting an EVSE charging post.

FIG. 15 is a block diagram of a method of installing a station of the disclosed technology.

### DETAILED DESCRIPTION

The disclosed technology includes a modular, expandable, prefabricated chassis for EV charging stations, capable of supporting a variety of EVSE charging posts. The chassis of the disclosed technology may be designed to support any number of EVSE charging posts, as well as any model or combination of models of EVSE charging posts.

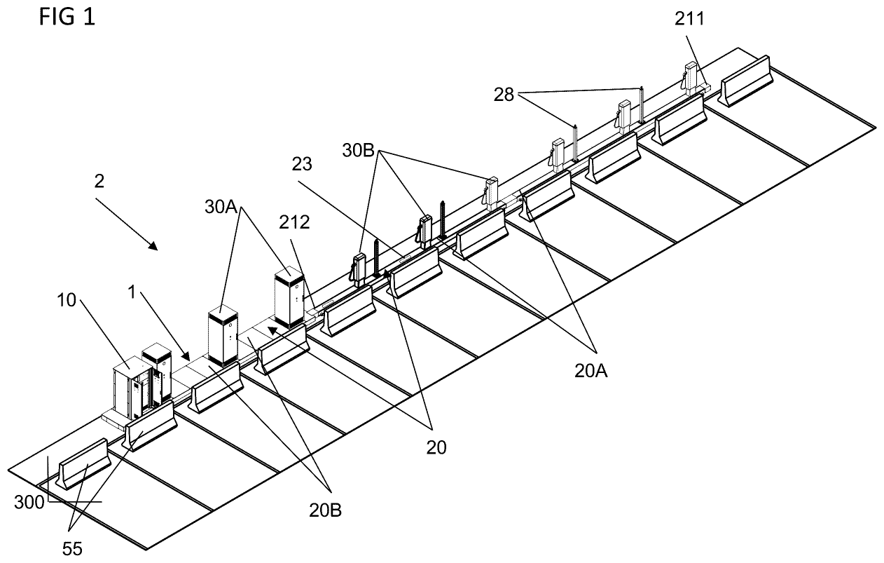

Most generally, and as shown in FIGS. 1, 7, 8, 10A, 10B, 11A, 12 and 13, the chassis 1 includes a connection cabinet 10 secured directly, or indirectly by means of a post, to a support housing 20. In this configuration, the connection cabinet is designed to receive electricity from a power source (i.e., a transformer) and distribute electricity to the EVSE charging posts 30A, 30B and associated elements by means of circuits within the connection cabinet, and power cabling and electrical wire electrically coupled with said circuits, extending from the connection cabinet and routed through the support housing.

As shown in FIGS. 1, 2A, 2B, 7, 8, 10A, 10B, 11A, 12 and 13, the support housing 20 is an enclosed, modular, raised platform, with a plurality of EVSE charging post positions defined thereon, and a port at each said EVSE charging post position. Cable supports 21 are secured within or integral with the interior of the support housing structure. The cable supports facilitate and manage routing of power cables, electrical wiring, and communications cables from the connection cabinet 10 to each EVSE charging post 30A, 30B and associated communications elements; further, cable supports can facilitate routing of cable to locations of the support housing structure intended for connection with charging posts which may be later installed on the chassis, and/or to the ends of the support housing where structure for future expansion of the chassis is provided, as hereinafter described. Suitable cable supports include cable trays, raceways, and conduits; other means for securing, supporting and protecting the cables may be similarly used. Particularly, raceways protect wires and cables from heat, humidity, corrosion, water intrusion and general physical threats; conduit has similar protective qualities. The cable supports may be fully secured to (or integral with) one or more interior surfaces of the support housing, may be secured at certain locations within the support housing, or may be wholly unsecured.

In the design of the cable support structures provided within the support housing of the disclosed technology, care should be taken to space power cables, electrical wires and communications cabling in accordance with the National Electric Code or similar regulatory requirements, or cable fill should be integrated within the cable support to ensure compliance.

The support housing 20 may be made from carbon steel, or other durable and weather resistant material sufficiently strong to support the weight of the EVSE charging posts and the connection cabinet. In some embodiments the sides of the support housing are made from tubular carbon steel, positioned between the top and bottom surfaces.

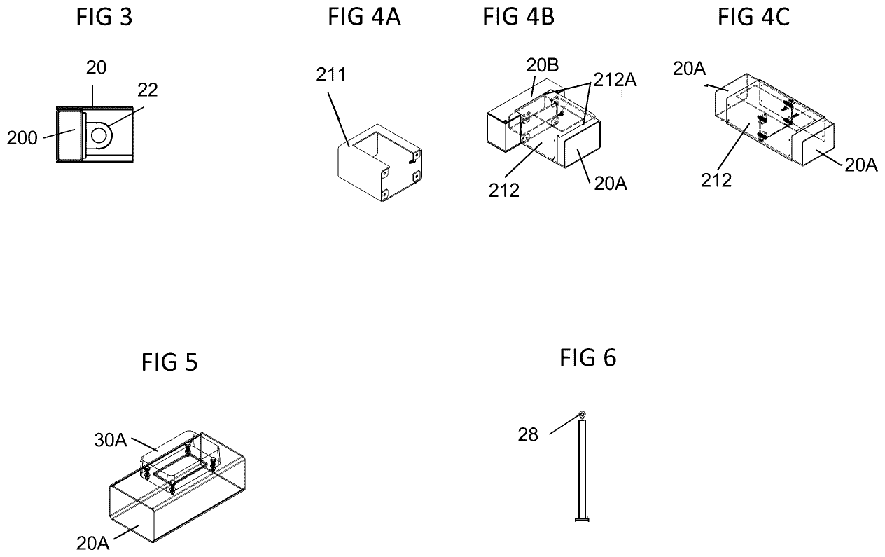

The support housing may have a depth of between 5″ (12.7 cm) and 1′ (30.48 cm), for example, sufficient to accommodate cable supports and the cables thereby supported and taking into account regulatory and industry standard cable fill requirements. As shown in FIG. 3, internal lifting lugs 22, such as carbon steel lifting lugs, may be secured to or integral with a wall of an exterior channel 200 of the support housing, to support the cabling or the cable supports, and to provided additional support to the support housing and additional protection for the cabling or the cable supports. In addition or alternatively, carbon steel cross braces may be secured within and about the interior of the support housing to provide additional support.

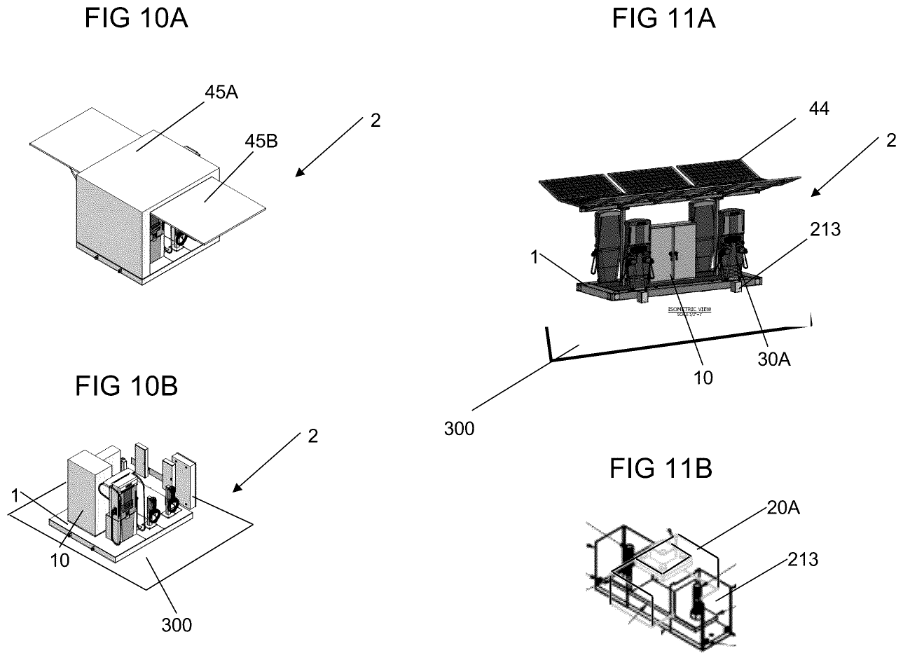

The support housing may be configured as an elongated tube 20A with a rectangular cross-section, may be configured as a rectangular pad 20B, or may include multiple pads or tubes, or a combination thereof, removably or permanently affixed one to another, as shown in FIGS. 1, 7, 8, 10A, 10B, 11A, 12 and 13. When multiple pads or tubes, or a combination thereof, are affixed one to another, the sides so affixed may have open ends or aligned ports to allow cable supports and/or cable to traverse from one pad/tube to an adjacent pad/tube. As shown in FIGS. 1, 10A and 10B, the support housing may configured to support different types and models of EV charging posts, such as for example a FLEX 180 KW charger manufactured by Heliox Energy 30A, and a 60/120/180 KW CCS1 charge column manufactured by Heliox Energy 30B. In some embodiments, as shown in FIG. 3, an exterior channel 200 is provided along the perimeter of support housing.

Access to the interior of the support housing and the cables may be provided by removable plates 23, such as steel plates, removably secured at locations about the top or side surfaces of the support housing by for example machine screws or bolts, the plates sized to cover apertures on such top or side surfaces of the support housing.

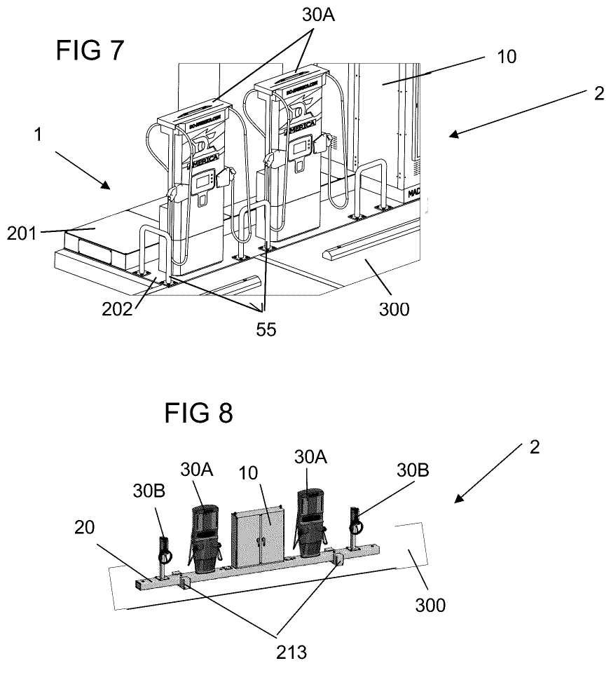

In some embodiments, such as the embodiment shown in FIG. 7, a portion of the support housing 201 may be raised for purposes of accommodating the cables and/or the cable supports, while a lateral adjacent portion of the support housing 202 may have a lower profile where at least some of the EVSE charging posts are positioned and secured. In this configuration the integrity of the cables is maintained by providing sufficient space therefor, while the height of one or more of the EVSE charging posts installed on the support housing is accessible to users who may be in wheelchairs or of short stature, facilitating compliance with The Americans with Disabilities Act and similar laws.

Some of the pads or tubes of the support housing may be provided with removable end caps 211, such as the embodiment thereof shown in FIG. 4A, to allow for future expansion of the chassis. As shown in FIGS. 1, 4B and 4C, for purposes of expanding the support housing the end cap 211 may be removed to expose an open support housing end; this open end is affixed to a corresponding open end of the expansion tube or pad, and an extender 212 is secured to the support housing over the point of affixation. When connecting two tubes or two pads, as shown in FIG. 4C, the extender is provided with three sides, and slightly larger dimensions, so that when the respective tubes/pads are secured by means of nuts and bolts, for example, the extender covers the tubes/pads at the point of affixation. When as shown in FIG. 4B a tube is extended from a pad, or a pad is extended from a tube, the extender covers the top and sides of the tube, with flanges 212A extending from the top surface to cover a portion of the top surfaces of each of the pad and the tube. In either configuration, the open ends of the original pad/tube and the extending element (pad or tube) provide a channel to allow cables to pass from the original support housing into the expansion element. This configuration may also be used in interconnecting tubes or pads of the original, unexpanded chassis structure, and or modules thereof.

The support housing may, when assembled, store additional cabling within its interior for purposes of expansion thereof or repair or upgrade of EVSE charging posts, thereby facilitating simple chassis expansion and the replacement of EVSE charging posts with upgraded EVSE charging posts on the support housing.

When the support housing includes one or more elongated tubes 20A, levelers 213 may be provided along the length of the support housing, affixed to the bottom of the elongated tube, to ensure that when installed on site the support housing is level to the horizon, regardless of the surface upon which it is installed (see, e.g., FIGS. 8, 11A and 11B). The levelers may be positioned as needed along the length of the support housing, and may present in one or more thicknesses to adjust the height of the support housing relative to and based upon variations of the ground surface.

Although the station could be assembled on site, many of the advantages of the disclosed technology are achieved when the chassis or the station, or modules of either, are assembled at a manufacturing facility and transported to the site. Therefore, means to lift the support housing onto a transportation vehicle, and remove the support housing from a transportation vehicle at the site, would be helpful. In some embodiments, particularly larger chassis or heavier modules, forklift apertures 27 as shown in FIG. 14 are provided on a side or end of the chassis or a module thereof, the apertures being sized and spaced to receive the forks of a standard forklift, thereby facilitating loading and unloading of the assembled chassis, station or modules thereof from the transportation vehicle. Smaller chassis may be provided with strong eye bolts 28 positioned on posts (see, e.g., FIGS. 1 and 6) which can be used to similarly lift the assembled station from a transportation vehicle and position it at the station site, using a small crane, pulley system, or similar equipment.

In the chassis of the disclosed technology and as shown in the embodiments of the figures, the connection cabinet 10 is affixed to the support housing 20, and aligned ports are provided at the bottom of the connection cabinet and at the top of the support housing, to supply power cables, electrical wire and communications cabling between the cabinet and the support housing. Similar ports are positioned along the support housing to provide power cables, electrical wire and communications cabling from the support housing for interconnection with the EVSE charging posts installed thereon.

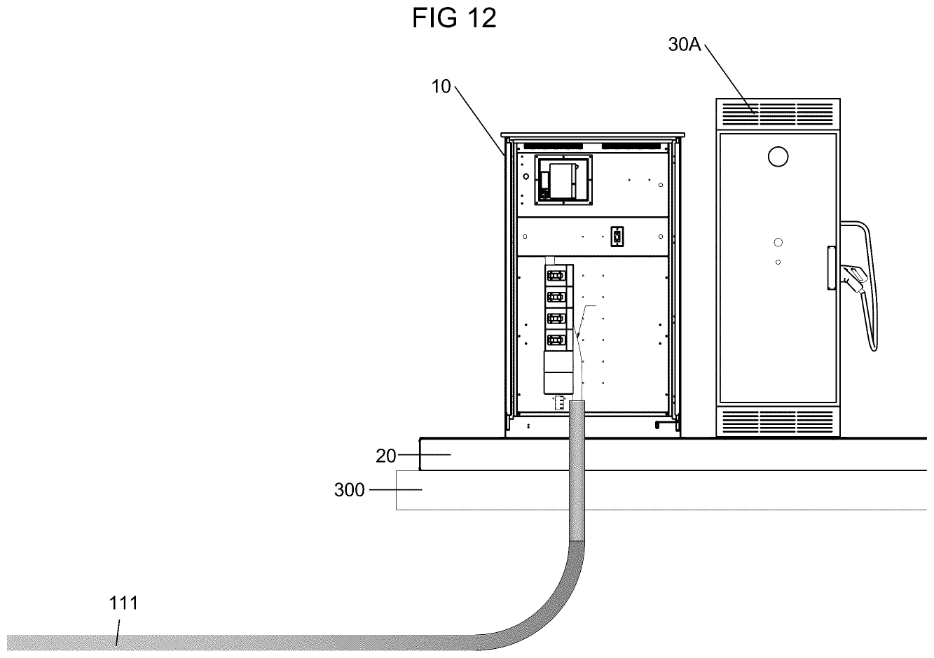

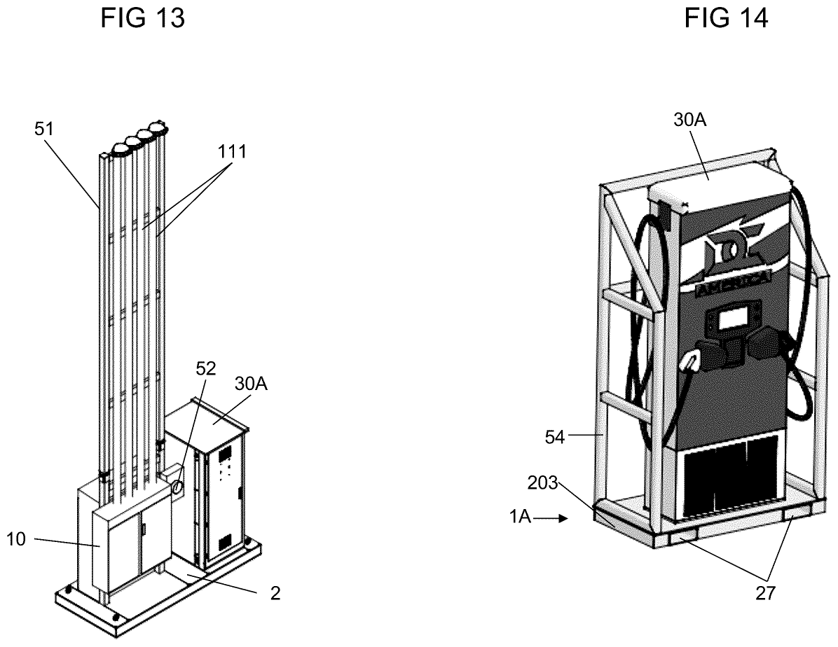

The connection cabinet 10 further includes a utility power cable entry port through a peripheral wall of the cabinet; this may include an overhead service line from the power source. In some embodiments, the utility power cable 111 is routed through an end of the support housing or provided underground (as shown in FIG. 12), beneath the chassis when positioned at the site, and through a port on the bottom surface of the support housing up through an entry port of the support housing to the cabinet (directly or through the cabinet post, if any).

As shown in FIG. 13, in an embodiment a rack 51 may be provided to support the utility power cables 111 and conduits for overhead supply to the connection cabinet 10. The power supply cables may be held taught with the rack by a plurality of guide wires. In this configuration an electrical meter 52 may be coupled with the utility power cables to measure electricity drawn from the utility power source, and the cable supports (e.g., conduits), thereby eliminating any digging to the electrical transformer at the site.

Wherever placed about the connection cabinet the entry port is sized for receiving utility power cables 111, originating from a utility power source, and distributed through a main distribution panel 13 of the cabinet. A current transformer cabinet may be secured to the chassis or positioned within the connection cabinet.

In installation the primary power cables 11A are separated from the ground cables 11B of the utility power cables, and connected to a master circuit breaker 14, while the ground cables are connected to a ground block or lug 15. By this configuration, a simple, local and easily accessible disconnect is provided by the circuit breaker, for maintenance, safety and convenience.

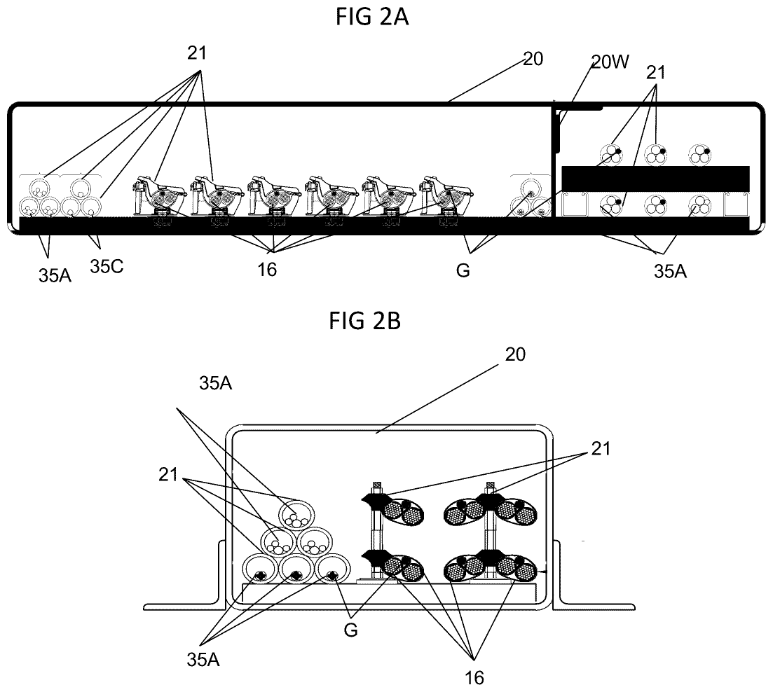

By means of the circuit provided in the cabinet, as further shown schematically in FIG. 9, the power is then distributed from the master circuit breaker into a plurality of supply cables 16 by means of distribution blocks or lugs 17A, which supply cables traverse through the exit ports at the bottom of the connection cabinet and through aligned ports of the support housing 20. These supply cables 16, supported by the cable supports, then traverse through the support housing to the intended location of the current (or future) EVSE charging posts, and supply power to the EVSE charging posts upon installation (see, e.g, FIGS. 2A and 2B). Suitable supply cables 16 may include 1,000 VDC cables, provided that the charging posts have 300 A fuses to protect the cables and the posts.

Further, power is distributed from the distribution blocks or lugs 17A of the cabinet to another circuit breaker 18 and a transformer 19, stepping the power down to 120 volts AC power, and then distributing the same through electrical wiring 35B, such as 480 VAC cables, by means of a series of fused terminal blocks 19A. Electrical wires 35A and communications cabling 35C are also provided, facilitating communication between the EVSE charging posts and a modem or LAN, for further communication to an offsite processor. Using the same or independent cable supports (see, e.g., FIGS. 2A and 2B), the power cables, electrical wires and communications cabling is supplied from the control cabinet, through the support housing to the intended location of installed or potential future EVSE charging posts and otherwise about the support housing, thereby supplying communications power and communication to/from components of the EVSE charging posts, and further to other components about the EVSE charging post and the support housing. As shown in FIGS. 2A and 2B, communications cabling 35A to send and receive information to/from the charging posts may present as CAN, ethernet, door interlock, estop or similar communications cabling. In the configuration shown in FIG. 2A, the alternating and direct current components are presented in separate compartments, isolated by an interior wall 20W, to maintain separation in cable management. As shown in FIG. 2A, Cat6 S/FTP cabling 35C may be provided to facilitate communication among the charging posts with a local area network. To manage the communications cabling, cable ties or ratchet clamps may be provided about the communications cabling or the conduits supporting the same, along the associated cable support structures within the support housing. In the configurations shown, ground wires are indicated as G.

The electrical wiring or, alternatively, energy from solar panels provided through an inverter as shown in FIG. 9, may provide power to an LED driver 40, housed within the connection cabinet and regulating the power, through a series of terminal blocks 40A and associated cabling, to a plurality of LED lights 41 positioned on the top surface of, or otherwise about, the support housing.

The electrical wiring 35A and communications cabling 35C may provide power and communication to one or more TV displays 42, which may be installed on a side of the connection cabinet, or otherwise about the station. Likewise, the electrical wiring may provide electrical energy to a power supply 43 of an Ethernet switch 43A, modem 43B, and other equipment necessary to transmit and receive information from and to the EVSE charging posts, over the Internet by means of a cellular network, hardwired cable network or satellite network. This communications equipment may be housed within the connection cabinet, and/or provided at other locations about the station.

In an embodiment, as shown in FIG. 14, the modules of the chassis 1 are prewired to connect with a separate chassis module 1A supporting an EVSE charging post; as shown in the figure, the EVSE charging post module may include protective support structure 54 comprising a plurality of interconnected posts, about the charging post to protect the same from inadvertent (or intentional) damage from a vehicle driving towards the post. In this modular embodiment, interconnecting power cables, electrical wire and communications cables are provided in the chassis 1, and the support housing 203 of the module(s) supporting the EVSE charging posts, for connection on site. In other embodiments (for example, as shown in FIGS. 1 and 7) bollards 55 or similar structure are provided to protect the charging posts from vehicular damage.

The disclosed technology further provides a modular EV charging station 2, including an expandable, prefabricated chassis supporting one or more EVSE charging posts, of the same or different models, for example as shown in FIGS. 1, 7, 8 and 13. The chassis 1 may be any of the embodiments of a chassis as hereinabove described, including a connection cabinet 10 secured to a support housing 20. In this configuration, the connection cabinet is designed to receive electricity from a power source (i.e., a transformer) and distribute the electricity to the EVSE charging posts 30A and/or 30B secured to the chassis, and to associated elements, by means of circuits within the connection cabinet, and power cables, electrical wire and communications cabling electrically coupled with said circuits, extending from the connection cabinet and routed through the support housing. Notably, in the station configuration of this embodiment the base of the EVSE charging posts 30A are secured to the support housing 203 of the module by nuts and bolts, as shown in FIG. 5.

As hereinabove described, the support housing 20 is an enclosed, modular, raised platform, with cable supports 21 secured within or integral with the interior of the support housing structure, wherein the cable supports facilitate and manage routing of power cables, electrical wire and communications cables from the connection cabinet 10 to each installed EVSE charging post 30A and/or 30B and associated communications elements. Further, cable supports can facilitate routing of cable to locations of the support housing structure available and intended for connection with future EV charging posts and/or to the ends of the support housing where structure for future expansion of the chassis is provided. Internal lifting lugs 22, such as carbon steel lifting lugs, may be secured about or integral with the interior of the support housing to support the cabling or the cable supports, and to provided additional support to the support housing and additional protection for the cabling or the cable supports. In addition or alternatively, carbon steel cross braces may be secured within the interior of the support housing to provide additional support.

The support housing may be configured as one or more elongated tubes 20A or pads 20B, or a combination thereof, removably or permanently affixed one to another, wherein when multiple pads or tubes, or a combination thereof, are affixed one to another, the sides so affixed may have open ends or aligned ports to allow cable supports and/or cable to traverse from one pad/tube to an adjacent pad/tube. Removable plates 23 may be secured to portions of the top surface of the support housing to provide access to the interior of the support housing and the cables therein, and removable end caps 211 and extenders 212 may be provided on ends of the pads or tubes of the housing to allow for future expansion of the station. As the station of the disclosed technology is intended to be assembled (wholly or in modules) at a manufacturing facility and transported to the site, means to lift the station from the transportation vehicle may be provided, such as for example forklift apertures 27 and/or strong eye bolts 28.

A plurality of ports are provided about the connection cabinet to receive the utility cables, and present the power cables, electrical wire and communications cables to the support housing and the EVSE charging posts installed thereon, configured and distributed as hereinabove described. With a single circuit breaker within the connection cabinet, a simple, local and easily accessible disconnect is provided at the station for maintenance, safety and convenience.

As hereinabove described, the station may further comprise LED lighting, powered by an LED Driver, internet communications equipment to communicate between the station and a remote location the status and operation of the EV charging posts and other equipment, such as TV displays.

In some embodiments of the station, as shown for example in FIG. 11A, one or more photovoltaic solar panels 44 may be installed above or about the support housing, which when coupled with a solar inverter or PV inverter 44A, converts the variable direct current output of the solar panel into a utility frequency alternating current which can supply power to various components of the disclosed technology, or to a battery for storage and later use by such components.

To protect stations of the disclosed technology in transportation and/or in use (allowing the same to be secured or closed, for example in the event of impending storms that could damage the station and its components components), an enclosing facility 45 may be provided with the station, the enclosing facility comprising a removable or affixed framed structure 45A with hinged or removable panels 45B positioned on one or more sides of the station, as shown in the embodiment of FIGS. 10A and 10B.

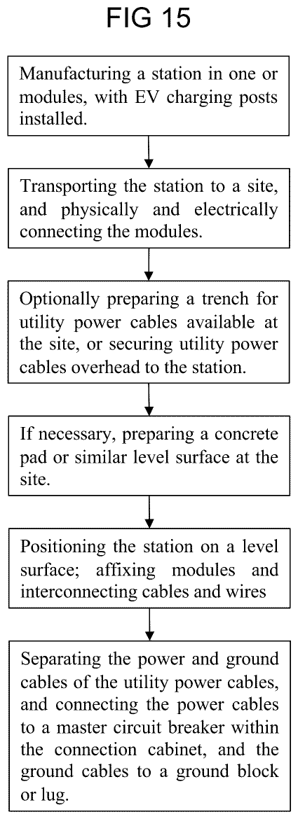

Finally, the disclosed technology regards a method for installation of an EV charging station, as shown in FIG. 15. The method including manufacturing a station in one or modules as hereinabove described through embodiments, with EV charging posts installed. Then transporting the station to a site, and physically and electrically connecting the modules. If necessary, preparing a trench for utility power cables available at the site, or securing utility power cables overhead to the station. If necessary, preparing a concrete pad or similar level surface 300 at the site. Then positioning the station on a level surface, affixing any modules, and interconnecting the electrical cables and wires between modules. Finally, separating the power and ground cables of the utility power cables, and connecting the power cables to a master circuit breaker within the connection cabinet, and the ground cables to a ground block or lug.

Although many embodiments of the disclosed technology have been shown in the figures provided herewith, and described herein, the same are not intended to be distinct embodiments and these and new embodiments may be developed using the various components herein described.

Various components and features described in connection with one embodiment of the invention are interchangeable with corresponding components and features of other embodiments, or may be incorporated into the other embodiments. It should be understood that these interchangeable or additional components and features can be combined or substituted in different configurations within the broader scope of the invention.

1. A modular, expandable, prefabricated chassis for EV charging stations useful in supporting a plurality of EVSE charging posts, the chassis comprising:
a support housing, the support housing presenting as an enclosed, modular, raised platform, with a plurality of EVSE charging post positions defined thereon, and a port at each said EVSE charging post position;
a connection cabinet affixed to the support housing, the connection cabinet having a master circuit breaker and electrical circuitry capable of receiving electricity from a power source, and distributing the electricity to a plurality of power supply cables and a plurality of electrical wires, wherein the connection cabinet further comprises communication cabling, and wherein the power supply cables, electrical wires and communication cabling are routed through the support housing to the EVSE charging post positions; and
a plurality of cable supports secured within or integral with an interior of the support structure, the cable supports facilitating and managing the routing of the power supply cables and the electrical wires through the support housing.

2. The chassis of claim 1, wherein the support housing further comprises a plurality of internal lifting lugs secured to or integral with a wall of an exterior channel of the support housing, to support the cabling or the cable supports, and to provided additional support to the support housing and additional protection for the cabling or the cable supports.

3. The chassis of claim 1, wherein the support housing comprises a plurality of connected elongated tubes with a rectangular cross-section, or a plurality of connected rectangular pads, or a connected combination of one or more elongated tubes with a rectangular cross section and one or more rectangular pads, and wherein the elongated tubes or the rectangular pads, or the elongated tubes and the rectangular pads, present with an open channel to facilitate the routing of the power supply cables and the electrical wires through the elongated tubes or the rectangular pads, or the elongated tubes and rectangular pads.

4. The chassis of claim 3, wherein a top or side surface of the support housing has one or more apertures, and wherein one or more plates are removably secured to the support housing, covering the apertures.

5. The chassis of claim 1, wherein a portion of the support housing is raised for purposes of accommodating the cables and the cable supports, while a lateral adjacent portion of the support housing has a lower profile, and wherein at least some of the EVSE charging post positions are positioned in the adjacent portion of the support housing.

6. The chassis of claim 3, wherein at least one of the elongated tubes or the rectangular pads include a removable end cap to allow for future expansion of the chassis, which when removed expose a channel through which power supply cables and electrical wires may pass.

7. The chassis of claim 1, wherein the support housing comprises one or more strong eye bolts positioned on posts, useful in lifting the chassis from a transportation vehicle and position it at a station site.

8. A modular, portable EV charging station comprising:
a chassis comprising:
a support housing, the support housing presenting as an enclosed, modular, raised platform, with a plurality of EVSE charging post positions defined thereon, and a port at each said EVSE charging post position;
a connection cabinet affixed to the support housing, the connection cabinet having a master circuit breaker and electrical circuitry capable of receiving electricity from a power source, and distributing the electricity to a plurality of power supply cables and a plurality of electrical wires, wherein the connection cabinet further comprises communication cabling, and wherein the power supply cables, electrical wires and communication cabling are routed through the support housing to the EVSE charging post positions; and
a plurality of cable supports secured within or integral with an interior of the support structure, the cable supports facilitating and managing the routing of the power supply cables and the electrical wires through the support housing; and
a plurality of EVSE charging posts affixed to the support housing at one or more of the EVSE charging post positions, wherein the power cables, the electrical wire and the communications cabling are electrically or communicatively coupled with the EVSE charging post.

9. The EV charging station of claim 8, wherein the support housing further comprises a plurality of internal lifting lugs secured to or integral with a wall of an exterior channel of the support housing, to support the cabling or the cable supports, and to provided additional support to the support housing and additional protection for the cabling or the cable supports.

10. The EV charging station of claim 8, wherein the support housing comprises a plurality of connected elongated tubes with a rectangular cross-section, or a plurality of connected rectangular pads, or a connected combination of one or more elongated tubes with a rectangular cross section and one or more rectangular pads, and wherein the elongated tubes or the rectangular pads, or the elongated tubes and the rectangular pads, present with an open channel to facilitate the routing of the power supply cables and the electrical wires through the elongated tubes or the rectangular pads, or the elongated tubes and rectangular pads.

11. The EV charging station of claim 10, wherein a top or side surface of the support housing has one or more apertures, and wherein one or more plates are removably secured to the support housing, covering the apertures.

12. The EV charging station of claim 8, wherein a portion of the support housing is raised for purposes of accommodating the cables and the cable supports, while a lateral adjacent portion of the support housing has a lower profile, and wherein at least some of the EVSE charging post positions are positioned in the adjacent portion of the support housing.

13. The EV charging station of claim 10, wherein at least one of the elongated tubes or the rectangular pads include a removable end cap to allow for future expansion of the chassis, which when removed expose a channel through which power supply cables and electrical wires may pass.

14. The EV charging station of claim 8, wherein the support housing comprises one or more strong eye bolts positioned on posts, useful in lifting the chassis from a transportation vehicle and position it at a station site.

15. The EV charging station of claim 8, wherein the support housing comprises a plurality of connected elongated tubes with a rectangular cross-section and a plurality of connected rectangular pads, wherein the elongated tubes and the rectangular pads present with an open channel to facilitate the routing of the power supply cables and the electrical wires through the elongated tubes and the rectangular pads, and wherein the plurality of EVSE charging posts include at least two different models of EVSE charging posts, a first model affixed to a rectangular pad, and a second model affixed to an elongated tube.

16. A method of installing an EV charging station at a site, the method comprising the steps of:
transporting an EV charging station to a site, the EV charging station comprising:
a chassis comprising:
a support housing, the support housing presenting as an enclosed, modular, raised platform, with a plurality of EVSE charging post positions defined thereon, and a port at each said EVSE charging post position;
a connection cabinet affixed to the support housing, the connection cabinet having a master circuit breaker and electrical circuitry capable of receiving electricity from a power source, and distributing the electricity to a plurality of power supply cables and a plurality of electrical wires, wherein the connection cabinet further comprises communication cabling, and wherein the power supply cables, electrical wires and communication cabling are routed through the support housing to the EVSE charging post positions; and
a plurality of cable supports secured within or integral with an interior of the support structure, the cable supports facilitating and managing the routing of the power supply cables and the electrical wires through the support housing; and
a plurality of EVSE charging posts affixed to the support housing at one or more of the EVSE charging post positions, wherein the power cables, the electrical wire and the communications cabling are electrically or communicatively coupled with the EVSE charging post;
positioning the EV charging station on a solid pad provided at the site; and
connecting utility lines to the connection cabinet of the chassis.

17. The method of installing an EV charging station at a site as provided in claim 16, further comprising the step of leveling the station by means of one or more levelers.

18. The method of installing an EV charging station at a site as provided in claim 16, wherein the support housing comprises a plurality of connected elongated tubes with a rectangular cross-section, or a plurality of connected rectangular pads, or a connected combination of one or more elongated tubes with a rectangular cross section and one or more rectangular pads, and wherein the elongated tubes or the rectangular pads, or the elongated tubes and the rectangular pads, present with an open channel to facilitate the routing of the power supply cables and the electrical wires through the elongated tubes or the rectangular pads, or the elongated tubes and rectangular pads.

19. The method of installing an EV charging station at a site as provided in claim 18, wherein at least one of the elongated tubes or the rectangular pads include a removable end cap, and wherein at the site the end cap is removed, exposing a channel through which power supply cables and electrical wires may pass, and another elongated tube or rectangular pad is secured to the at least one of the elongated tubes or rectangular pads by means of an extender.
